(19) United States
(12) Patent Application Publication
(10) Pub. No.: US 2020/0228105 A1
(43) Pub. Date: Jul. 16, 2020

(54) CLOCKING CIRCUIT ARRANGEMENT AND METHOD OF FORMING THE SAME

(71) Applicant: Agency for Science, Technology and Research, Singapore (SG)

(72) Inventors: Jun Zhou, Singapore (SG); Xin Liu, Singapore (SG); Jingjing Lan, Singapore (SG)

(21) Appl. No.: 16/648,192

(22) PCT Filed: Oct. 1, 2018
(86) PCT No.: PCT/SG2018/050496

§ 371 Date: Mar. 17, 2020

(30) Foreign Application Priority Data
Oct. 3, 2017 (SG) 10201708122W

(51) Int. Cl. H03K 5/1252; H03K 5/24

(52) U.S. Cl. CPC H03K 5/1252; H03K 5/249

(57) ABSTRACT

Various embodiments may relate to a clocking circuit arrangement. The clocking circuit arrangement may include a clock source, as well as a global monitoring circuit arrangement including a monitoring tunable clock buffer, a reference clock buffer, a glitch capturing circuit arrangement, and a voltage generation circuit arrangement. The clocking circuit arrangement may further include a main circuit arrangement including one or more further tunable clock buffers.

### CROSS-REFERENCE TO RELATED APPLICATION

This application claims the benefit of priority of Singapore application No. 10201708122 W filed Oct. 3, 2017, the contents of it being hereby incorporated by reference in its entirety for all purposes.

### TECHNICAL FIELD

Various aspects of this disclosure relate to a clocking circuit arrangement. Various aspects of this disclosure relate to a method of forming a clocking circuit arrangement.

### BACKGROUND

Radiation causes soft errors in the digital integrated circuits (ICs). This happens when the cosmic radiation strikes certain parts of the semiconductor material. This phenomenon usually causes two types of errors. The first type of error arises due to radiation effects over a long period of time, and is termed as “total ionizing dose (TID)”. The second type of error arises because of the immediate result of a single radiant charged particle, and is known as “single event effects (SEE)”.

The TID is a long-term effect of radiation due to trapped high energy particles in the gates of transistors. This alters the threshold voltage of the transistor, and causes functional errors and leakage current. The TID is closely related to the gate thickness of transistors. The thicker the gate, the greater the TID effect. It has been found that the TID effect becomes significantly smaller when the thickness of the gate oxide is less than 12 nm, which corresponds to IC fabrication technologies below 0.35 μm. Therefore, for modern deep submicron (DSM) IC fabrication technologies (e.g. 65 nm, 40 nm), the resilience to the TID effect is inherently high.

On the other hand, the SEE has become increasingly problematic for ICs in the deep submicron range. This is due to continuously decreasing feature sizes, lower supply voltages, and higher operating frequencies, which cause a reduction in the noise margins of IC designs. The SEE includes single event upset (SEU) and single event latch-up (SEL). SEL occurs when radiation-induced high energy particles accidentally turn on parasitic transistors in silicon. The turning on of the parasitic transistors causes large current and heat dissipation, which may damage the silicon transistors permanently. The SEU occurs when a high energy particle hits the transistor channel. It usually causes bit flipping in memories (e.g. in flip-flops, static random access memory (SRAM)). or glitches in internal signals of ICs.

Currently, there are some techniques to address SEL and SEU issues. One common way to reduce SEL is to add guard rings in the circuit layout. For SEU, the design of radiation-resilient flip-flop and SRAM circuits may be able to prevent or correct radiation-induced errors occurring inside these circuits. However, if the errors occur in the clock network, all of the circuits using the clock would be affected. In fact, the errors in clock network are more serious than errors in cells/blocks due to high fan-out clocking designs, where the same clock signal is used by many cells/blocks. As such, a single error in the clock network may result in errors at different parts of the IC, and may be likely to cause system failure.

### SUMMARY

Various embodiments may relate to a clocking circuit arrangement. The clocking circuit arrangement may include a clock source configured to generate a clock source signal. The clocking circuit arrangement may further include a global monitoring circuit arrangement. The global monitoring circuit arrangement may include a monitoring tunable clock buffer in electrical connection with the clock source, the tunable clock buffer configured to generate a monitoring clock signal based on a first adjustable voltage, a second adjustable voltage, and the clock source signal. The global monitoring circuit arrangement may also include a reference clock buffer in electrical connection with the clock source, the reference clock buffer configured to generate a reference clock signal including a reference delay based on a first fixed reference voltage, a second fixed reference voltage, and the clock source signal. The global monitoring circuit arrangement may additionally include a glitch capturing circuit arrangement in electrical connection to the monitoring tunable clock buffer and the reference clock buffer, the glitch capturing circuit arrangement configured to detect a glitch included in the monitoring clock signal based on the monitoring clock signal and the reference clock signal. The global monitoring circuit arrangement may also include a voltage generation circuit arrangement in electrical connection with the glitch capturing circuit arrangement. The clocking circuit arrangement may further include a main circuit arrangement. The main circuit arrangement may include one or more further tunable clock buffers in electrical connection with the clock source, each of the one or more further tunable clock buffers configured to generate an output clock signal based on the first adjustable voltage, the second adjustable voltage, and the clock source signal.

The glitch capturing circuit arrangement may be configured to transmit one or more first control signals and one or more second control signals to the voltage generation circuit arrangement upon detecting the glitch included in the monitoring clock signal. The voltage generation circuit arrangement may also be in electrical connection with the monitoring tunable clock buffer and each of the one or more further tunable clock buffers for transmitting the first adjustable voltage and the second adjustable voltage to the monitoring tunable clock buffer and each of the one or more tunable clock buffers. The voltage generation circuit arrangement may be configured to adjust the first adjustable voltage and the second adjustable voltage upon receiving the one or more first control signals and the one or more second control signals from the glitch capturing circuit arrangement so that the output clock signal generated by at least one tunable clock buffer of the one or more tunable clock buffers includes a suitable delay for compensating a corresponding glitch in an input signal provided to the at least one tunable clock buffer.

Various embodiments may relate to a method of forming a clocking circuit arrangement. The method may include providing a clock source configured to generate a clock source signal. The method may also include connecting a global monitoring circuit arrangement to the clock source. The global monitoring circuit arrangement may include a monitoring tunable clock buffer in electrical connection with the clock source, the tunable clock buffer configured to generate a monitoring clock signal based on a first adjustable voltage, a second adjustable voltage, and the clock source signal. The global monitoring circuit arrangement may also include a reference clock buffer in electrical connection with the clock source, the reference clock buffer configured to generate a reference clock signal including a reference delay based on a first fixed reference voltage, a second fixed reference voltage, and the clock source signal. The global monitoring circuit arrangement may further include a glitch capturing circuit arrangement in electrical connection to the monitoring tunable clock buffer and the reference clock buffer, the glitch capturing circuit arrangement configured to detect a glitch included in the monitoring clock signal based on the monitoring clock signal and the reference clock signal. The global monitoring circuit arrangement may additionally include a voltage generation circuit arrangement in electrical connection with the glitch capturing circuit arrangement. The method may also include connecting a main circuit arrangement to the clock source. The main circuit arrangement may include one or more further tunable clock buffers in electrical connection with the clock source, each of the one or more further tunable clock buffers configured to generate an output clock signal based on the first adjustable voltage, the second adjustable voltage, and an input signal based on the clock source signal.

The glitch capturing circuit arrangement may be configured to transmit one or more first control signals and one or more second control signals to the voltage generation circuit arrangement upon detecting a glitch included in the monitoring clock signal. The voltage generation circuit arrangement may also be in electrical connection with the monitoring tunable clock buffer and each of the one or more further tunable clock buffers for transmitting the first adjustable voltage and the second adjustable voltage to the monitoring tunable clock buffer and each of the one or more tunable clock buffers. The voltage generation circuit arrangement may be configured to adjust the first adjustable voltage and the second adjustable voltage upon receiving the one or more first control signals and the one or more second control signals from the glitch capturing circuit arrangement so that the output clock signal generated by at least one tunable clock buffer of the one or more tunable clock buffers includes a suitable delay for compensating a corresponding glitch in the input signal provided to the at least one tunable clock buffer.

### BRIEF DESCRIPTION OF THE DRAWINGS

The invention will be better understood with reference to the detailed description when considered in conjunction with the non-limiting examples and the accompanying drawings, in which:

FIG. 1A is a schematic showing a radiation-resilient flip-flop which is able to correct a radiation-induced error.

FIG. 1B is a schematic showing a simple implementation of a clock glitch removal technique.

FIG. 1C is a schematic showing a more complex implementation of the clock glitch removal technique.

FIG. 2 shows a general illustration of a clocking circuit arrangement according to various embodiments.

FIG. 3 shows a schematic illustrating a method of forming a clocking circuit arrangement according to various embodiments.

FIG. 4A shows a schematic of a clock network or clocking circuit arrangement according to various embodiments.

FIG. 4B shows a schematic of a tunable clock buffer (TCB) according to various embodiments.

FIG. 4C is a schematic illustrating a global monitoring circuit arrangement according to various embodiments.

FIG. 4D shows a schematic of the integrity check module according to various embodiments.

FIG. 4E shows a schematic of the voltage generation circuit arrangement according to various embodiments.

FIG. 5 shows a plot of voltage (in volts or V) as a function of time (in nanoseconds or ns) showing the various simulation waveforms of the clocking circuit arrangement according to various embodiments.

FIG. 6 shows a table comparing the clocking circuit arrangement according to various embodiments and some of the conventional devices.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or circuit arrangements are analogously valid for the other methods or circuit arrangements. Similarly, embodiments described in the context of a method are analogously valid for a circuit arrangement, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may also be used herein to mean that the deposited material may be formed “indirectly on” the implied side or surface with one or more additional layers being arranged between the implied side or surface and the deposited material. In other words, a first layer “over” a second layer may refer to the first layer directly on the second layer, or that the first layer and the second layer are separated by one or more intervening layers. Further, in the current context, a layer “over” or “on” a side or surface may not necessarily mean that the layer is above a side or surface. A layer “on” a side or surface may mean that the layer is formed in direct contact with the side or surface, and a layer “over” a side or surface may mean that the layer is formed in direct contact with the side or surface or may be separated from the side or surface by one or more intervening layers.

A “circuit” may be understood as any kind of a logic implementing entity, which may be special purpose circuitry or a processor executing software stored in a memory, firmware, or any combination thereof. Thus, in various embodiments, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail may also be understood as a “circuit” in accordance with various alternative embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may seek to address the abovementioned issues. Various embodiments may seek to address errors or glitches occurring in clock networks (also referred to as clocking (or clock) circuit arrangements, or clocking (or clock) circuits).

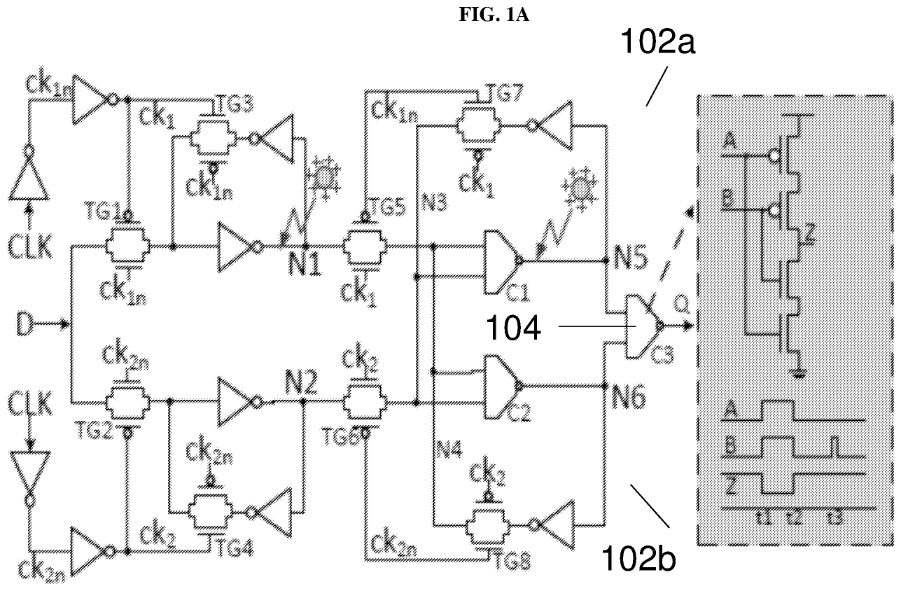

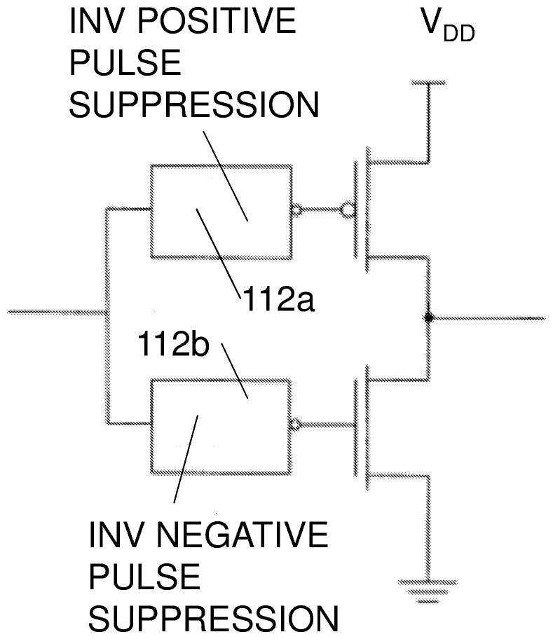

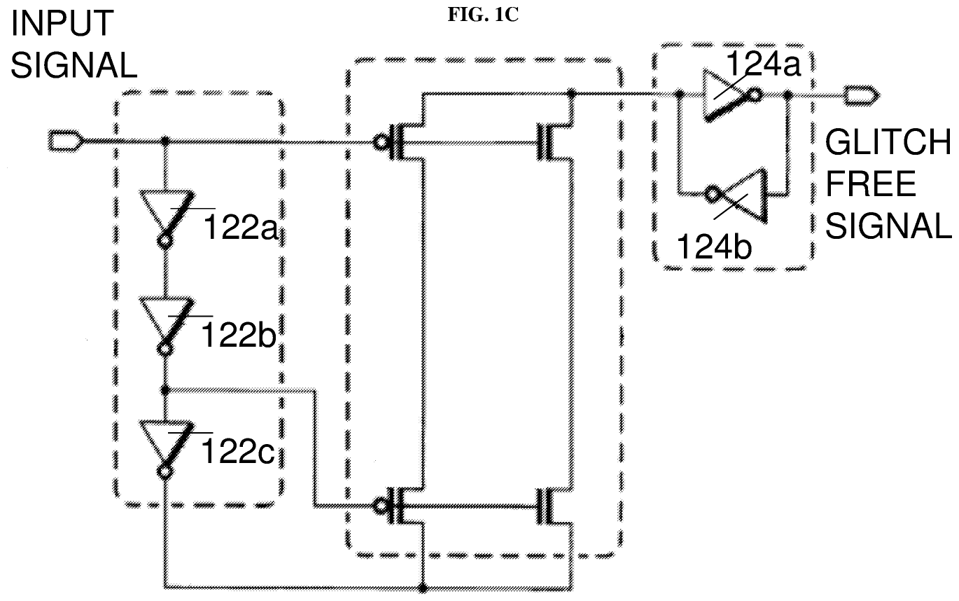

In the past, many techniques have been proposed to address the SEU errors in digital ICs. For example, redundant structures and C elements have been proposed to achieve radiation-resilient flip-flops. As shown in FIG. 1A, unlike conventional flip-flops, there are two data/clock paths in the radiation-resilient flip-flop. FIG. 1A is a schematic showing a radiation-resilient flip-flop which is able to correct a radiation-induced error. The outputs of the two data/clock paths 102a, 102b are merged at a C element 104. If an error occurs at one of the data/clock paths 102a, 102b, the output of the C element 104 would not change. The output of the C element would change only when both the data/clock both paths 102a, 102b change. In this way, the radiation-induced error may be corrected, and may not propagate to subsequent circuits.

For SRAM, there are also some techniques to correct the SEU errors. These include adopting error correction coding (ECC) schemes, and designing the SRAM circuits in a way that the SEU-induced charges would be quickly discharged.

The radiation-resilient techniques discussed above may be able to correct the SEU errors occurring inside the cell/block.

However, if the error occurs within the clock network, the error may propagate to all the subsequent circuits (e.g. flip-flop, SRAM circuits) which use the clock. This error resides in the clock inputs, and may not be able to be fixed by the techniques mentioned above. In order to address the SEU errors in clock network, a clock glitch removing technique has been proposed FIG. 1B.

FIG. 1B is a schematic showing a simple implementation of a clock glitch removal technique. As shown in FIG. 1B. in this technique, delay control circuits 112a, 112b are used to generate delay for clock buffers. The delay can be tuned so that any SEU induced glitch shorter than the delay cannot propagate to the output of the clock buffer. As the rise and fall delay is separate, the two delay control circuits 112a, 112b are added to control the pull-up path delay and pull-down path delay.

FIG. 1C is a schematic showing a more complex implementation of the clock glitch removal technique. In the circuit shown in FIG. 1C, the delay is achieved by a chain of inverters 122a-c, and a pair of cross-coupled inverter 124a-b are added at the output to keep the data. However, the implementations shown in FIGS. 1B-C would face a problem when used to remove or address SEU-induced glitches in the clock network. As the delay is pre-fixed while the glitch information is not pre-known, a short delay may not be sufficient to cover the glitch. On the other hand, if the delay is too long, it may heavily distort the clock signal.

Glitches may be short pulses generated by radiated particles bombarding the IC chip. In various embodiments, these short pulses in the clock network may be filtered by increasing the intrinsic delay of each clock buffer. Intuitively, if the delay of the buffer is longer than the width of the glitch, it may be filtered out.

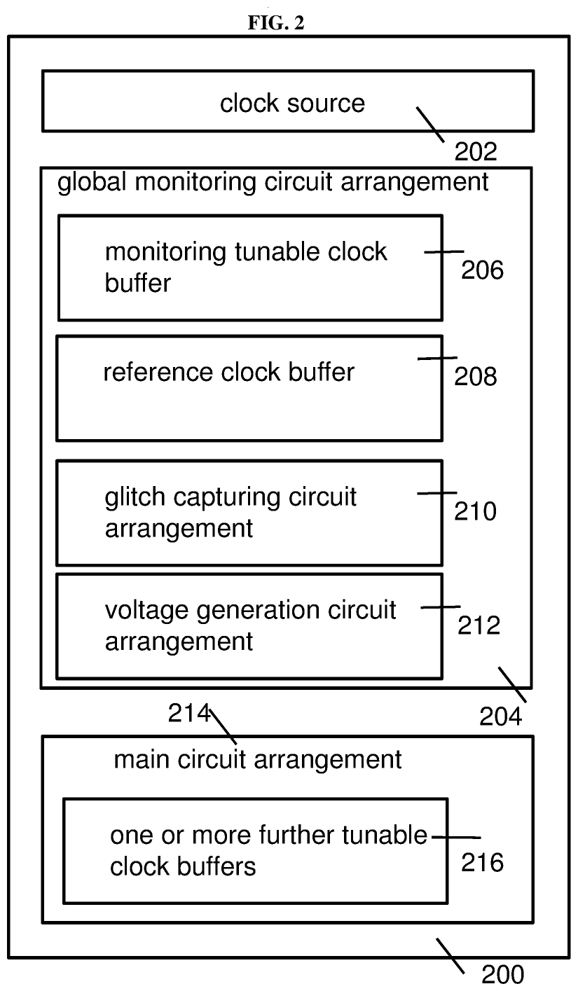

FIG. 2 shows a general illustration of a clocking circuit arrangement 200 according to various embodiments. The clocking circuit arrangement 200 may include a clock source 202 configured to generate a clock source signal. The clocking circuit arrangement 200 may further include a global monitoring circuit arrangement 204.

The global monitoring circuit arrangement 204 may include a monitoring tunable clock buffer 206 in electrical connection with the clock source 202, the tunable clock buffer 206 configured to generate a monitoring clock signal based on a first adjustable voltage, a second adjustable voltage, and the clock source signal. The global monitoring circuit arrangement 204 may also include a reference clock buffer 208 in electrical connection with the clock source 202, the reference clock buffer 208 configured to generate a reference clock signal including a reference delay based on a first fixed reference voltage, a second fixed reference voltage, and the clock source signal. The global monitoring circuit arrangement 204 may additionally include a glitch capturing circuit arrangement 210 in electrical connection to the monitoring tunable clock buffer 206 and the reference clock buffer 208, the glitch capturing circuit arrangement 210 configured to detect a glitch included in the monitoring clock signal based on the monitoring clock signal and the reference clock signal. The global monitoring circuit arrangement 204 may also include a voltage generation circuit arrangement 212 in electrical connection with the glitch capturing circuit arrangement 210.

The clocking circuit arrangement 200 may further include a main circuit arrangement 214. The main circuit arrangement 214 may include one or more further tunable clock buffers 216 in electrical connection with the clock source 202, each of the one or more further tunable clock buffers 216 configured to generate an output clock signal based on the first adjustable voltage, the second adjustable voltage, and the clock source signal.

The glitch capturing circuit arrangement 210 may be configured to transmit one or more first control signals and one or more second control signals to the voltage generation circuit arrangement 212 upon detecting the glitch included in the monitoring clock signal. The voltage generation circuit arrangement 212 may also be in electrical connection with the monitoring tunable clock buffer 206 and each of the one or more further tunable clock buffers 216 for transmitting the first adjustable voltage and the second adjustable voltage to the monitoring tunable clock buffer 206 and each of the one or more tunable clock buffers 216.

The voltage generation circuit arrangement 212 may be configured to adjust the first adjustable voltage and the second adjustable voltage upon receiving the one or more first control signals and the one or more second control signals from the glitch capturing circuit arrangement 210 so that the output clock signal generated by at least one tunable clock buffer of the one or more tunable clock buffers includes a suitable delay for compensating a corresponding glitch in an input signal provided to the at least one tunable clock buffer.

In other words, the clocking circuit arrangement 200 may include a global monitoring circuit arrangement 204 and a main circuit arrangement 214. The main circuit arrangement 214 may include one or more clock buffers 216 which may be tunable (by two adjustable voltages, e.g. V_{PBIAS} and V_{NBIAS}). A clock buffer 216 may receive an input signal based on a clock source signal (which is generated by a clock source 202), and may generate an output clock signal based on the input signal, tuned by the two adjustable voltages. The global monitoring system 204 may include a monitoring tunable clock buffer 206, a reference clock buffer 208, a glitch capturing circuit arrangement 210, and a voltage generation circuit arrangement 212. Similar to the clock buffers 216, the monitoring tunable clock buffer 206 may also be controlled by the two adjustable voltages, while the reference clock buffer 208 is connected to fixed reference voltages. Both the monitoring tunable clock buffer 206 and the reference clock buffer 208 may receive an input signal based on the clock source signal. The input signal provided to the tunable clock buffer 206 and the reference clock buffer may have a glitch. As the reference clock buffer 208 has a very large delay, the glitch may be filtered out, and the reference clock signal generated by the reference clock buffer may be devoid of a glitch. In contrast, before any adjustment, the monitoring tunable clock buffer 206 may not generate a sufficient delay to remove the glitch, and the glitch may appear in the monitoring clock signal generated by the monitoring tunable clock buffer 206. By comparing the monitoring signal and the reference clock signal, the glitch in the monitoring signal may be detected. The glitch in the monitoring signal may be detected by the glitch capturing circuit arrangement 210. Upon detection of the glitch in the monitoring signal, control signals may be sent from the glitch capturing circuit arrangement 210 to the voltage generation circuit arrangement 212 so that the voltage generation circuit arrangement 212 adjusts the two adjustable voltages. The two adjustable voltages may be adjusted so that at least one tunable clock buffer 216 may now generate an output clock signal including a delay sufficient to compensate a corresponding glitch in the input signal provided to the tunable clock buffer 216.

The clocking circuit arrangement 200 may alternatively be referred to as a clock network, an adaptive clock glitch removal circuit, a clock circuit arrangement, a clocking circuit, or a clock circuit.

In the current context, a first electrical element in electrical connection with a second electrical element may refer to situations in which the first electrical element directly connected to the second electrical element, and also to situations in which the first electrical element is indirectly connected to the second electrical element via one or more intervening electrical elements.

In various embodiments, the first adjustable voltage (V_{PBIAS}) may be any voltage selected from 0 V to VDD. The second adjustable voltage (V_{NBIAS}) may be any voltage selected from 0 V to VDD. In other words, each of the first adjustable voltage and the second adjustable voltage may be a positive voltage or ground (0V).

The glitch may be generated by exposing the clock source 202 or clock arrangement 200 to radiation. The glitch may be due to a single event effect (SEE), such as single event upset (SEU). If the glitch is not rectified or addressed, the glitch may propagate to the remaining of the clocking arrangement 200, as well as other circuits in electrical connection to the clocking circuit arrangement 200. The tunable buffer may be configured to introduce a delay so that the glitch is addressed or at least partially addressed.

The glitch in the input signal provided to the monitoring tunable clock buffer 206 and the reference clock buffer 208, and the glitch in the input signal provided to the at least one tunable clock buffer 216 may arise from the same cause, e.g. the same radiation event. The input signal provided to the monitoring tunable clock buffer 206 and the reference clock buffer 208 may be the same as or may be similar to the input signal provided to the at least one tunable buffer. The glitch in the input signal provided to the monitoring tunable clock buffer 206 and the reference clock buffer 208, and the glitch in the input signal provided to the at least one tunable clock buffer 216 may occur at the same time duration in a clock pulse. The glitch in the input signal provided to the monitoring tunable clock buffer 206 may subsequently appear as a glitch in the monitoring clock signal generated by the monitoring tunable clock buffer 206. Accordingly, the glitches in the input provided to the monitoring tunable clock buffer 206 (and the reference clock buffer 208), in the input signal provided to the monitoring tunable clock buffer 206, and monitoring clock signal generated by the monitoring tunable clock buffer 206 may correspond to one another.

In various embodiments, the glitch capturing circuit arrangement 210 may include a first flip flop in electrical connection with the monitoring tunable clock buffer 206, a second flip flop in electrical connection with the reference clock buffer 208, and an integrity check circuit arrangement (alternatively referred to as an integrity check module) in electrical connection with the first flip flop and the second flip flop.

The first flip flop may include a clock input port in electrical connection with an output of the monitoring tunable clock buffer. The first flip flop may further include a data input port (D), and an output port (Q) in electrical connection with the integrity check circuit arrangement. The first flip flop may additionally include an inverted output port (Q̅) in electrical connection with the data input port.

The second flip flop may include a clock input port in electrical connection with an output of the reference clock buffer. The second flip flop may further include a data input port (D), and an output port (Q) in electrical connection with the integrity check circuit arrangement. The second flip flop may additionally include an inverted output port (Q̅) in electrical connection with the data input port.

The integrity check circuit arrangement may include an exclusive OR gate (XOR gate) having an input in electrical connection with the first flip flop and the second flip flop. The integrity check circuit arrangement may also include a shift-up register in electrical connection to an output of the exclusive OR gate (XOR gate), and a shift-down register in electrical connection to the output of the exclusive OR gate (XOR gate).

The exclusive OR gate (XOR gate) may be configured to detect the glitch included in the monitoring clock signal by comparing a first signal from the first flip flop and a second signal from the second flip flop. The exclusive OR gate (XOR gate) may be configured to transmit a glitch flag signal to the shift-up register and the shift-down register upon detecting the glitch (included in the monitoring signal).

The voltage generation circuit arrangement 212 may alternatively be referred to as a voltage generator. The voltage generation circuit arrangement 212 may include a voltage source. The voltage source may be configured to generate a fixed voltage. The voltage generation circuit arrangement 212 may further include a voltage divider in electrical connection with the voltage source, the voltage divider configured to generate different voltages based on the fixed voltage of the voltage source. In various embodiments, a first end of the voltage divider may be connected to the voltage source, while a second end of the voltage divider may be connected to ground. The voltage divider may include a plurality of resistors connected in series for generating the different voltages.

The voltage generation circuit arrangement 212 may be configured to adjust the first adjustable voltage upon receiving the one or more first control signals from the glitch capturing circuit arrangement 210. The voltage generation circuit arrangement 212 may be configured to adjust the second adjustable voltage upon receiving the one or more second control signals from the glitch capturing circuit arrangement 210.

The voltage generation circuit arrangement 212 may additionally include a first multiplexer in electrical connection with the voltage divider and the shift-up register, and a second multiplexer in electrical connection with the voltage divider and the shift-down register.

The first and second multiplexers may be analogue multiplexers. The first multiplexer may include a first plurality of electrical lines configured to receive the different voltages, each line including a switch. The second multiplexer may include a second plurality of electrical lines configured to receive the different voltages, each line including a switch. The switch included in each line of the first plurality of electrical lines may make up a first plurality of switches. Similarly, the switch included in each line of the second plurality of electrical lines may make up a second plurality of switches.

The shift-up register may be configured to transmit the one or more first control signals to the first multiplexer upon receiving the glitch flag signal, thereby adjusting the first adjustable voltage by controlling the first plurality of switches. Similarly, the shift-down register may be configured to transmit the one or more second control signals to the second multiplexer upon receiving the glitch flag signal, thereby adjusting the second adjustable voltage by controlling the second plurality of switches.

The voltage generation voltage may be configured so that at any one time, only one of the first plurality of switches is activated (i.e. switched on or turned on) to select one voltage of the plurality of voltages for generating the first adjustable voltage, and only one of the second plurality of switches is activated (i.e. switched on or turned on) to select one voltage of the plurality of voltages for generating the second adjustable voltage.

In various embodiments, the monitoring tunable clock buffer 206, the reference clock buffer 208, and the one or more further tunable clock buffers 216 may each include an inverter having an input and an output, and a tuning circuit arrangement in electrical connection with the input of the inverter. The inverter may be also referred to as an internal tunable delay inverter.

The tuning circuit arrangement of each of the monitoring tunable clock buffer 206, the reference clock buffer 208, and the one or more further tunable clock buffers 216 may include a first n-channel field effect transistor having a control electrode, a first controlled electrode and a second controlled electrode; a second n-channel field effect transistor having a control electrode, a first controlled electrode and a second controlled electrode; a first p-channel field effect transistor having a control electrode, a first controlled electrode and a second controlled electrode; and a second p-channel field effect transistor having a control electrode, a first controlled electrode and a second controlled electrode.

In the current context, a control electrode of a field effect transistor may be referred as a gate electrode. In various embodiments, the first controlled electrode of the field effect transistor may be a source electrode, and the second controlled electrode of the field effect transistor may be a drain electrode. In various other embodiments, the first controlled electrode of the field effect transistor may be a drain electrode, and the second controlled electrode of the field effect transistor may be a source electrode.

The first controlled electrode of the first p-channel field effect transistor may be connected to a supply voltage (which may be a fixed voltage). The first controlled electrode of the second p-channel field effect transistor may be connected to the second controlled electrode of the first p-channel field effect transistor. The first controlled electrode of the first n-channel field effect transistor may be connected to the second controlled electrode of the second p-channel field effect transistor and to the input of the inverter. The first controlled electrode of the second n-channel field effect transistor may be connected to the second controlled electrode of the first n-channel field effect transistor. The second controlled electrode of the second n-channel field effect transistor may be connected to ground. The control electrode of the first p-channel field effect transistor and the control electrode of the second n-channel field effect transistor may be in electrical connection with the clock source.

The control electrode of the second p-channel field effect transistor included in each of the monitoring tunable clock buffer and the one or more further tunable clock buffers may be in electrical connection with the voltage generation circuit arrangement to receive the first adjustable voltage. In addition, the control electrode of the first n-channel field effect transistor included in each of the monitoring tunable clock buffer and the one or more further tunable clock buffers may be in electrical connection with the voltage generation circuit arrangement to receive the second adjustable voltage.

The control electrode of the second p-channel field effect transistor included in the reference clock buffer may be in electrical connection with the voltage generation circuit arrangement to receive the first fixed reference voltage. The control electrode of the first n-channel field effect transistor included in the reference clock buffer may be in electrical connection with the voltage generation circuit arrangement to receive the second fixed reference voltage.

In various embodiments, the reference clock signal may be devoid of the glitch due to the reference delay.

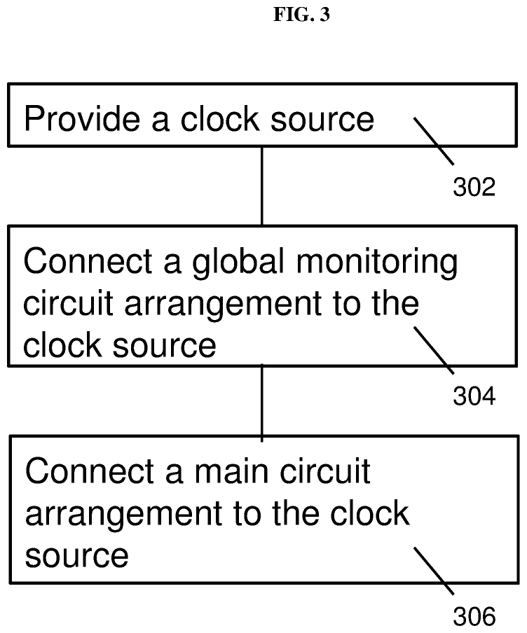

FIG. 3 shows a schematic illustrating a method of forming a clocking circuit arrangement according to various embodiments. The method may include, in 302, providing a clock source configured to generate a clock source signal. The method may also include, in 304, connecting a global monitoring circuit arrangement to the clock source. The global monitoring circuit arrangement may include a monitoring tunable clock buffer in electrical connection with the clock source, the tunable clock buffer configured to generate a monitoring clock signal based on a first adjustable voltage, a second adjustable voltage, and the clock source signal. The global monitoring circuit arrangement may also include a reference clock buffer in electrical connection with the clock source, the reference clock buffer configured to generate a reference clock signal including a reference delay based on a first fixed reference voltage, a second fixed reference voltage, and the clock source signal. The global monitoring circuit arrangement may further include a glitch capturing circuit arrangement in electrical connection to the monitoring tunable clock buffer and the reference clock buffer, the glitch capturing circuit arrangement configured to detect a glitch included in the monitoring clock signal based on the monitoring clock signal and the reference clock signal. The global monitoring circuit arrangement may additionally include a voltage generation circuit arrangement in electrical connection with the glitch capturing circuit arrangement.

The method may also include, in 306, connecting a main circuit arrangement to the clock source. The main circuit arrangement may include one or more further tunable clock buffers in electrical connection with the clock source, each of the one or more further tunable clock buffers configured to generate an output clock signal based on the first adjustable voltage, the second adjustable voltage, and an input signal based on the clock source signal.

The glitch capturing circuit arrangement may be configured to transmit one or more first control signals and one or more second control signals to the voltage generation circuit arrangement upon detecting a glitch included in the monitoring clock signal. The voltage generation circuit arrangement may also be in electrical connection with the monitoring tunable clock buffer and each of the one or more further tunable clock buffers for transmitting the first adjustable voltage and the second adjustable voltage to the monitoring tunable clock buffer and each of the one or more tunable clock buffers.

The voltage generation circuit arrangement may be configured to adjust the first adjustable voltage and the second adjustable voltage upon receiving the one or more first control signals and the one or more second control signals from the glitch capturing circuit arrangement so that the output clock signal generated by at least one tunable clock buffer of the one or more tunable clock buffers includes a suitable delay for compensating a corresponding glitch in the input signal provided to the at least one tunable clock buffer.

In other words, a clocking circuit arrangement may be formed by coupling a global monitoring circuit and a main circuit arrangement to a clock source.

The method may also include connecting the main circuit arrangement to the clocking circuit arrangement.

Various embodiments may relate to an adaptive clock glitch removal circuit for radiation-resilient clock network.

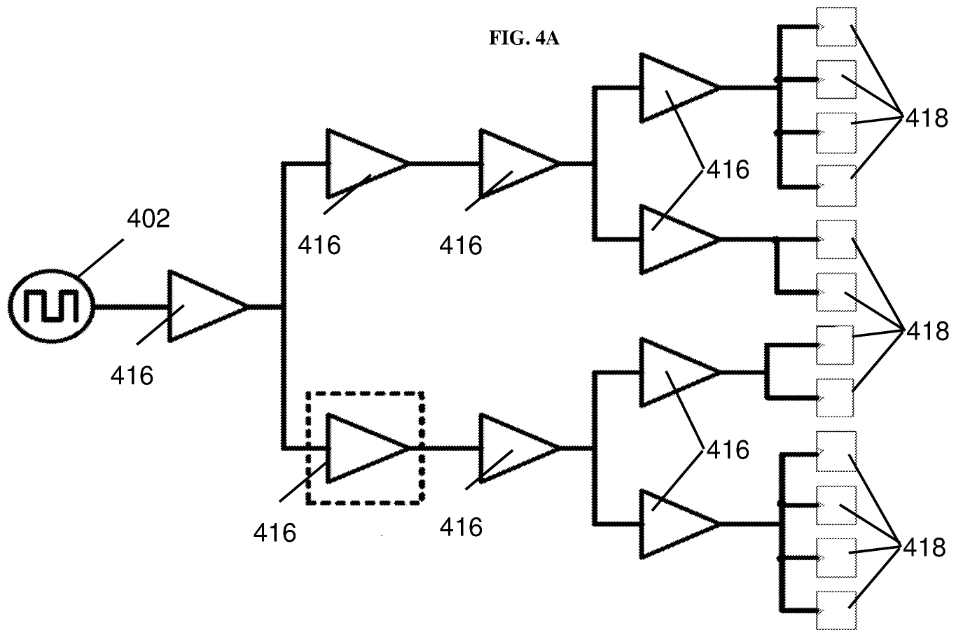

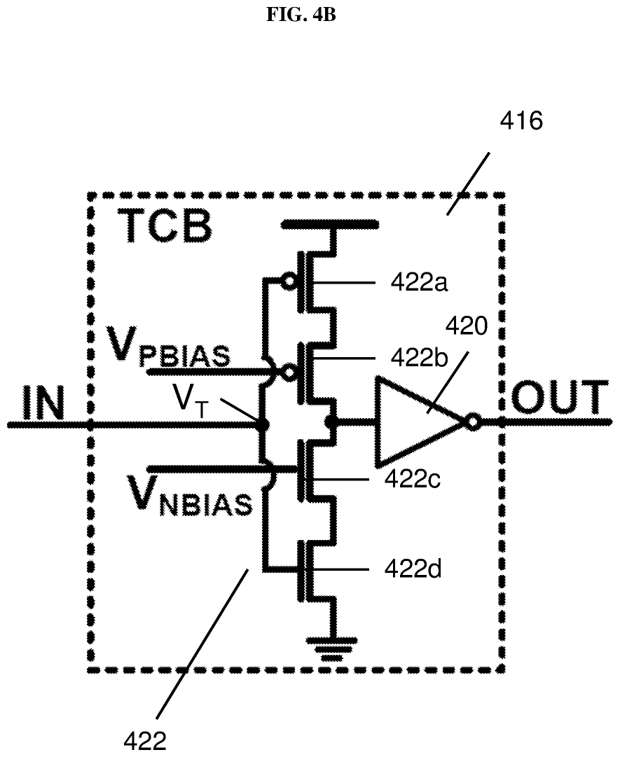

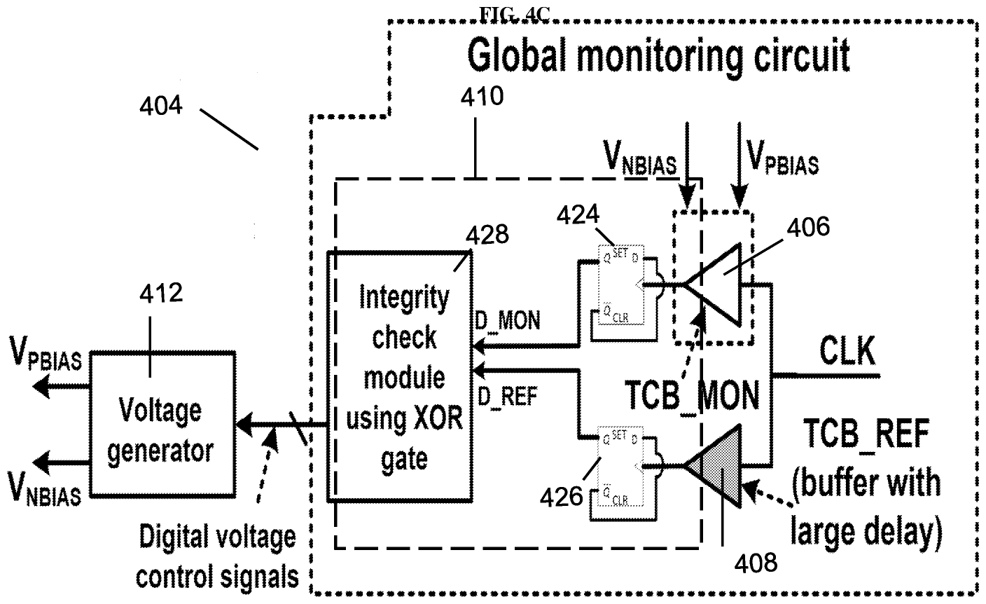

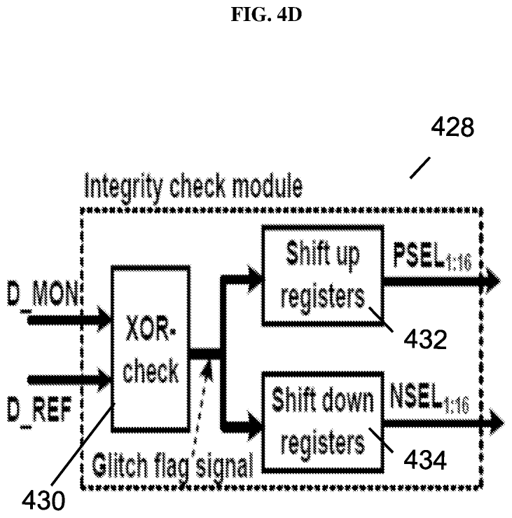

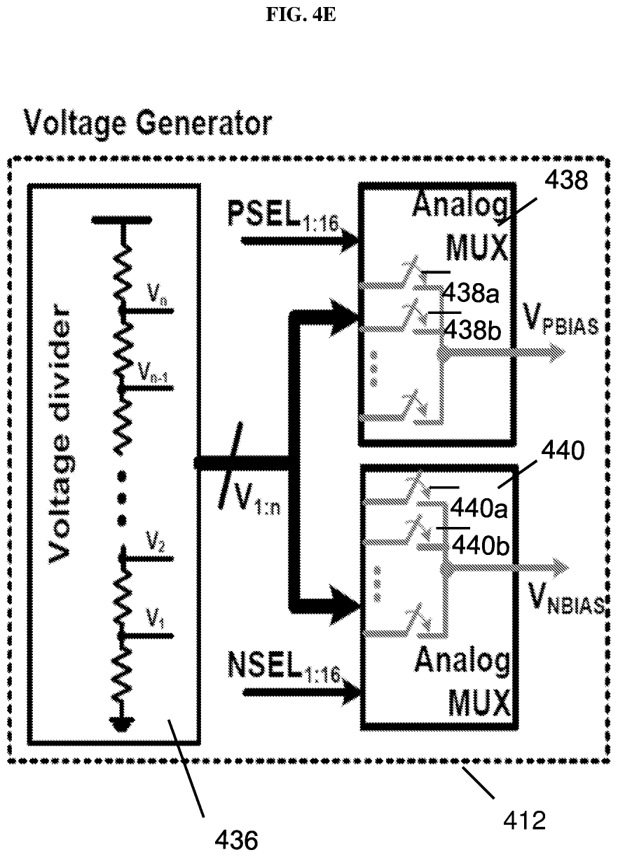

FIG. 4A shows a schematic of a clock network or clocking circuit arrangement 400 according to various embodiments. The clock network or clocking circuit arrangement 400 may employ a clock tree model, and may include multiple clock buffers 416 which drive a large number of flip-flops 418 across the chip. In various embodiments, each clock buffer 416 may be a tunable clock buffer (TCB) as shown in FIG. 4B. FIG. 4B shows a schematic of a tunable clock buffer (TCB) according to various embodiments.

A difference between the TCB 416 and a conventional clock buffer may be that the TCB has an internal tunable delay inverter 420. The internal tunable delay inverter 420 may controlled by two adjustable bias signals, i.e. two adjustable voltages (V_{PBIAS} and V_{NBIAS}). V_{PBIAS} and V_{NBIAS} may be shared across the circuit arrangement 400 or chip. By controlling these adjustable signals or voltages, the intrinsic delay of each clock buffer 416 may be increased or adjusted adaptively to filter out glitches caused by radiation event.

As shown in FIG. 4B, the TCB 416 may further include a tuning circuit arrangement in electrical connection with an input of the inverter 420. The tuning circuit arrangement may include a first p-channel field effect transistor 422a (having a control electrode, a first controlled electrode and a second controlled electrode), a second p-channel field effect transistor 422b (also having a control electrode, a first controlled electrode and a second controlled electrode), a first n-channel field effect transistor 422c (also having a control electrode, a first controlled electrode and a second controlled electrode), and a second n-channel field effect transistor 422d (also having a control electrode, a first controlled electrode and a second controlled electrode).

The first controlled electrode of the first p-channel field effect transistor 422a may be connected to a supply voltage. The first controlled electrode of the second p-channel field effect transistor 422b may be connected to the second controlled electrode of the first p-channel field effect transistor 422a. The first controlled electrode of the first n-channel field effect transistor 422c may be connected to the second controlled electrode of the second p-channel field effect transistor 422b and to the input of the inverter 420. The first controlled electrode of the second re-channel field effect transistor 422d may be connected to the second controlled electrode of the first n-channel field effect transistor 422c. The second controlled electrode of the second n-channel field effect transistor 422d may be connected to ground.

The control electrode of the first p-channel field effect transistor 422a and the control electrode of the second n-channel field effect transistor 422d may be in electrical connection with the clock source 402. The TCB 416 may receive an input signal (IN) based on or be derived from the clock source signal. In various embodiments, the input signal may be the clock source signal.

The control electrode of the second p-channel field effect transistor 422b may be in electrical connection with a voltage generation circuit arrangement 412 (shown in FIG. 4C) to receive the first adjustable voltage, V_{PBIAS}. The control electrode of the first n-channel field effect transistor 422c may be in electrical connection with the voltage generation circuit arrangement or module 412 to receive the second adjustable voltage, V_{NBIAS}.

The voltage VT as shown in FIG. 4B may be based on the equivalent resistances across transistors 422a-d, which in turn may be based on the two adjustable voltages as well as the input signal.

The output clock signal (OUT) generated by the tunable clock buffer 416, i.e. the output signal of inverter 420, may be based on the two adjustable voltages in addition to the input signal.

As highlighted above, the two adjustable voltages may be generated by the voltage generation circuit arrangement or module 412 as shown in FIG. 4C. FIG. 4C is a schematic illustrating a global monitoring circuit arrangement 404 according to various embodiments. The global monitoring circuit arrangement 404 may include a monitoring tunable clock buffer 406 (TCB_MON), and a reference clock buffer 408 (TCB_REF). The monitoring tunable clock buffer 406 and the reference clock buffer 408 may be tunable clock buffers (TCBs). The clock source signal from the clock network 400, i.e. from the clock source 402, may be fed to the monitoring tunable clock buffer 406 and the reference clock buffer 408. The monitoring tunable clock buffer 406 (TCB_MON) may share the same adjustable voltages (V_{PBIAS} and V_{NBIAS}) as the TCBs 416.

On the other hand, the reference clock buffer 408 (TCB_REF) may be connected to fixed reference voltages, which provide a very large delay, e.g. a value more than 1 nanosecond (ns) or more than 2 ns, to make sure that all the glitches are filtered out. A typical glitch formed by SEU may be between a few of tens of picoseconds (ps) to less than 1 nanosecond (ns). Accordingly, a large delay of more than 1 ns or more than 2 ns may be able to filter out the glitches. As such, the reference clock signal may be free of glitches.

The global monitoring circuit arrangement 404 may include a glitch capturing circuit arrangement 410. The glitch capturing circuit arrangement 410 may include a first flip flop 424 connected to an output of the monitoring tunable clock buffer 406, and a second flip flop 426 connected to an output of the reference clock buffer 408.

The outputs of the monitoring tunable clock buffer 406 (TCB_MON) and reference clock buffer 408 (TCB_REF) may be used to clock the two flip flops 424, 426 as shown in FIG. 4C. Both flip flops 424, 426 may have their inverted outputs (Q) connected to the inputs (D) so that the outputs (Q) invert at every rising edge of the clock source signals. The global monitoring circuit arrangement 404 may also include an integrity check circuit arrangement or module 428

For the first flip flop 424 which connects to the monitoring tunable clock buffer 406 (TCB_MON), the rising edge may be due to the actual clock source signal or due to the glitch. For second flip-flop 426 which connects to the reference clock buffer 408 (TCB_REF), the rising edge may always be due to the actual clock source signal, as the TCB_REF's delay is set large enough to filter out any possible glitches. Thus, in the event that there is a glitch at the output of the monitoring tunable clock buffer 406 (TCB_MON), the output signal of the first flip flop 424, D_MON may change, while the output signal of the second flip flop 426, D_REF, may remain the same. The glitch in the monitoring clock signal generated by the monitoring tunable clock buffer 406 (TCB_MON), may thus cause D_MON and D_REF to be different.

The difference between D_MON and D_REF (i.e. caused by or due to the glitch) may be captured by the integrity check module 428, which may generate an error pulse (e.g. a glitch flag signal) by using an exclusive OR gate (XOR gate). Every glitch at the output of TCB_MON may result in an error pulse. When an error pulse is generated, both flip flops 424, 426 may get reset (automatically) to ensure one glitch only generates one error pulse. The error pulses generated by the XOR gate in the integrity check module 428 may be used to clock the shift registers in the integrity check module 428 to produce appropriate digital control signals to the voltage generator 412. These digital control signals may in turn trigger the change of the controlling word signals, and thus the change of the V_{PBIAS} and V_{NBIAS} of TCB_MON 406 and TCBs 416. Accordingly, a closed loop may be formed to tune the V_{PBIAS} and V_{NBIAS} of TCBs until the glitch in the output clock signal is removed.

A clock signal, such as the clock source signal may include a series of consecutive repeating clock pulses. In various embodiments, the glitch may occur in any clock pulse of the clock source signal. When a glitch of a particular clock pulse is detected by the glitch capturing circuit arrangement 410, the voltage generation circuit arrangement 412 may be triggered to adjust the adjustable voltages so that each tunable clock buffer 416 introduces an additional delay to compensate for the glitch. TCB_MON 406 upon receiving the subsequent clock pulses may introduce a similar delay (since TCB_MON 406 is biased with the adjusted adjustable voltages V_{NBIAS}, V_{PBIAS}) so that if the delay (due to adjusted adjustable voltages V_{NBIAS}, V_{PBIAS}) is sufficient to compensate for the glitch, the glitch capturing module 410 may subsequently not detect a difference between signals D_MON and D_REF, and may not subsequently trigger a further adjustment of the adjustable voltages V_{NBIAS}, V_{PBIAS}. On the other hand, if the delay (due to adjusted adjustable voltages V_{NBIAS}, V_{PBIAS}) is still not sufficient to fully compensate for the glitch, the glitch capturing module 410 may subsequently still detect a difference between signals D_MON and D_REF, and may subsequent trigger a further adjustment of the adjustable voltages V_{NBIAS}, V_{PBIAS} to further compensate for the glitch. This may be repeated for subsequent clock pulses until the glitch is fully compensated. In other words, the adjustable voltages V_{NBIAS}, V_{PBIAS} may be adjusted until the glitch is fully compensated.

FIG. 4D shows a schematic of the integrity check module 428 according to various embodiments. As highlighted above, the integrity check module 428 may include an exclusive OR gate 430 (XOR gate) having an input in electrical connection with the first flip flop 424 and the second flip flop 426. The integrity check module 428 may also include a shift-up register 432 in electrical connection to an output of the exclusive OR gate 430 (XOR gate), and a shift-down register 434 in electrical connection to the output of the exclusive OR gate 430 (XOR gate).

If D_MON signal and D_REF signal differ from each other, the XOR gate 430 may generate an error pulse (i.e. glitch flag) which clocks the shift-up register 432 and shift-down register 434. These registers 432, 434 may produce first control signals, e.g. 16P-select signals (PSEL_{1:16}) and second control signals, e.g. 16 N-select signals (NSEL_{1:16}), respectively. PSEL_{1:16} may count up while NSEL_{1:16} may count down.

FIG. 4E shows a schematic of the voltage generation circuit arrangement 412 according to various embodiments. The voltage circuit arrangement 412 may include a voltage divider 436 in electrical connection with a voltage source, the voltage divider 436 configured to generate different voltages based on a fixed voltage of the voltage source. A first end of the voltage divider 436 may be connected to the fixed voltage, while a second end of the voltage divider may be connected to ground. The voltage circuit arrangement 412 may also include a first multiplexer 438 in electrical connection with the voltage divider 436 and the shift-up register 432. The voltage circuit arrangement 412 may further include a second multiplexer 440 in electrical connection with the voltage divider 436 and the shift-down register 434.

The voltage divider 436 may be constructed by cascading N identical resistors in series to produce or generate a number (N) of voltage levels V₁ . . . Vₙ. PSEL_{1:16} and NSEL_{1:16} from the integrity check module 428 may be sent to the inputs of the analogue multiplexers 438, 440 respectively to choose or select one of the voltage levels, i.e. from V₁ to Vₙ. In other words, the first multiplexer 438 may be configured so that the first multiplexer 438 selects one voltage of the plurality of voltages upon receiving PSEL_{1:16}, and may be configured to output the first adjustable voltage, V_{PBIAS}, based on the one voltage selected. The second multiplexer 440 may be configured so that the second multiplexer 440 selects one voltage of the plurality of voltages upon receiving NSEL_{1:16}, and may be configured to output the second adjustable voltage, V_{NBIAS}, based on the one voltage selected. As seen from FIG. 4E, the first multiplexer 438 may include a first plurality of switches (438a, b . . . ), and the second multiplexer 440 may include a second plurality of switches (440a, b . . . ).

During operation, the shift-up register 432 may transmit the first control signals, PSEL_{1:16}, to the first multiplexer 438 upon receiving the glitch flag signal, thereby adjusting the first adjustable voltage by controlling the first plurality of switches (438a, b . . . ) in the first multiplexer 438. The shift-down register 434 may transmit the second control signals, NSEL_{1:16}, to the second multiplexer 440 upon receiving the glitch flag signal, thereby adjusting the second adjustable voltage by controlling the second plurality of switches (440a, b . . . ) in the second multiplexer 440.

The first and second control signals may be one-hot coded. For instance, only one of the first control signals PSELᵢ may be at ‘1’ while the rest may be at ‘0’. Similarly, only one of the second control signals NSELᵢ may be at ‘1’ while the rest may be at ‘0’. For example, if PSEL_{[3]}=1, then V_{PBIAS}=V3.

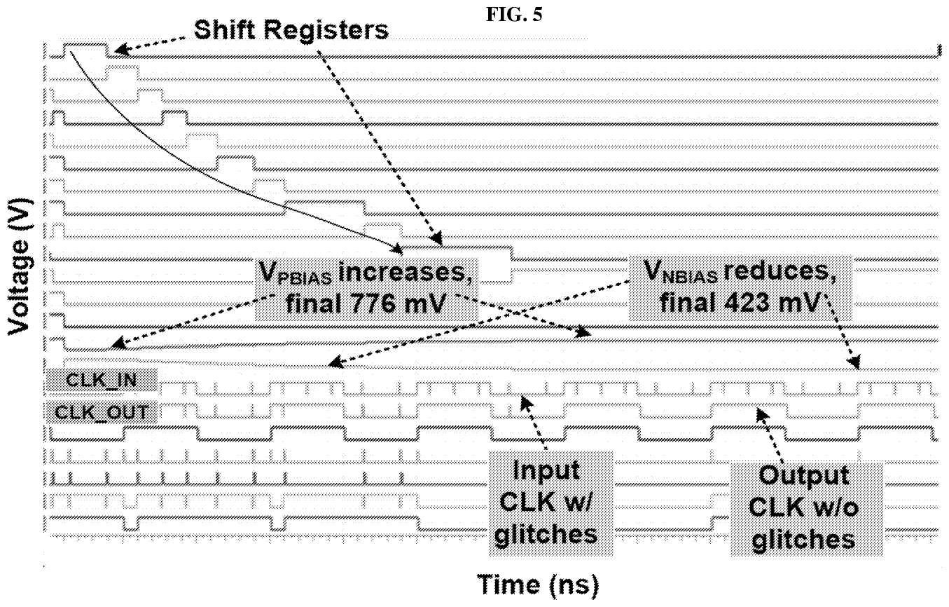

Various embodiments may be implemented using a suitable complementary metal oxide semiconductor (CMOS) technology, e.g. 65 nm complementary metal oxide semiconductor (CMOS) technology. FIG. 5 shows a plot of voltage (in volts or V) as a function of time (in nanoseconds or ns) showing the various simulation waveforms of the clocking circuit arrangement according to various embodiments. A glitch generator may be used to inject glitches into the original clock signal for testing purposes. At the beginning of the simulation, V_{PBIAS} and V_{NBIAS} may be set to 0 V and 1.2 V, respectively. As glitches are present in the clock waveform, the XOR-check is triggered, and the V_{PBIAS} and V_{NBIAS} are adaptively tuned. As can be seen in FIG. 5, V_{PBIAS} increases while V_{NBIAS} decreases to increase the buffer delay. The adaptive tuning may gradually reduce the number of glitches by increasing the delay of TCBs. V_{PBIAS} and V_{NBIAS} are finally adjusted to 776 mV and 223 mV respectively, and the glitches may be completely eliminated. The adaptive tuning is then automatically stopped. Various embodiments may not only ensure that the glitches are removed, but may also minimize the impact of the delay on the clock signal.

Various embodiments may relate to an adaptive clock glitch remover circuit for radiation-resilient clock network to remove the clock glitches induced by radiation. Various embodiments may involve the monitoring of the actual glitch profile and the adaptively tuning of the delay of the tunable clock buffers to remove the glitches. Various embodiments may ensure that the glitch is removed while minimizing the delay impact to the clock signal.

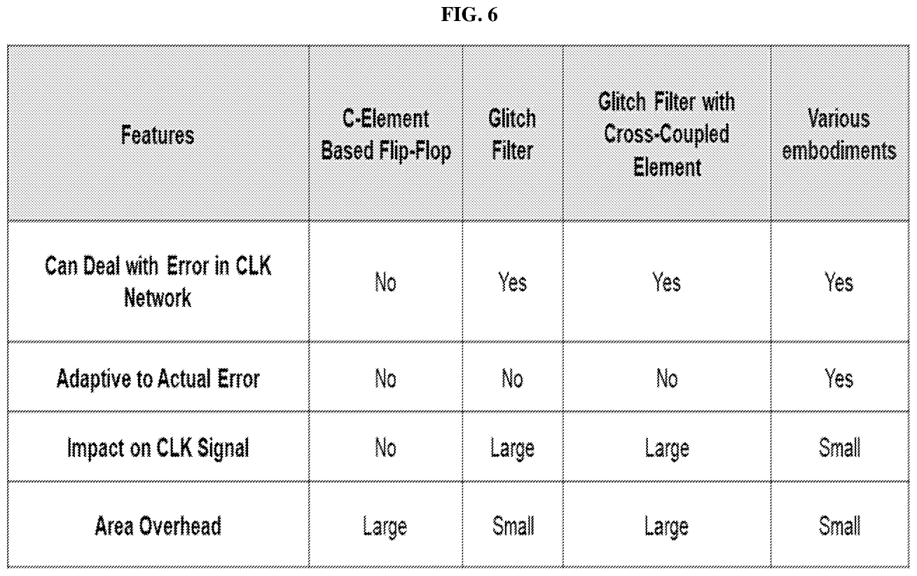

FIG. 6 shows a table comparing the clocking circuit arrangement according to various embodiments and some of the conventional devices.

Most existing techniques may deal with radiation-induced errors in sequential circuits (e.g. flip-flops), but may not be able to deal with radiation-induced errors (i.e. glitches) in clock networks.

There are some existing techniques that deal with glitches in a clock network by adding delay elements in the clock buffer to filter out the glitches. However, as the delay is pre-fixed, the delay may be either too small to filter the glitch, or may be too large to distort the clock signal.

Various embodiments may propose an adaptive clock glitch removal circuit. Various embodiments may monitor the actual glitch profile and may adjust the delay adaptively to make it sufficient to filter out the glitches while minimizing the impact to the clock signal.

The two flip flop-based scheme for glitch monitoring may have small circuit overhead compared to monitoring schemes with digital control.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A clocking circuit arrangement comprising:
a clock source configured to generate a clock source signal;
a global monitoring circuit arrangement comprising:
a monitoring tunable clock buffer in electrical connection with the clock source, the tunable clock buffer configured to generate a monitoring clock signal based on a first adjustable voltage, a second adjustable voltage, and the clock source signal;
a reference clock buffer in electrical connection with the clock source, the reference clock buffer configured to generate a reference clock signal comprising a reference delay based on a first fixed reference voltage, a second fixed reference voltage, and the clock source signal;
a glitch capturing circuit arrangement in electrical connection to the monitoring tunable clock buffer and the reference clock buffer, the glitch capturing circuit arrangement configured to detect a glitch comprised in the monitoring clock signal based on the monitoring clock signal and the reference clock signal; and
a voltage generation circuit arrangement in electrical connection with the glitch capturing circuit arrangement; and
a main circuit arrangement comprising:
one or more further tunable clock buffers in electrical connection with the clock source, each of the one or more further tunable clock buffers configured to generate an output clock signal based on the first adjustable voltage, the second adjustable voltage, and the clock source signal;
wherein the glitch capturing circuit arrangement is configured to transmit one or more first control signals and one or more second control signals to the voltage generation circuit arrangement upon detecting the glitch comprised in the monitoring clock signal;
wherein the voltage generation circuit arrangement is also in electrical connection with the monitoring tunable clock buffer and each of the one or more further tunable clock buffers for transmitting the first adjustable voltage and the second adjustable voltage to the monitoring tunable clock buffer and each of the one or more tunable clock buffers; and
wherein the voltage generation circuit arrangement is configured to adjust the first adjustable voltage and the second adjustable voltage upon receiving the one or more first control signals and the one or more second control signals from the glitch capturing circuit arrangement so that the output clock signal generated by at least one tunable clock buffer of the one or more tunable clock buffers comprises a suitable delay for compensating a corresponding glitch in an input signal provided to the at least one tunable clock buffer.

2. The circuit arrangement according to claim 1,
wherein the glitch capturing circuit arrangement comprises:
a first flip flop in electrical connection with the monitoring tunable clock buffer;
a second flip flop in electrical connection with the reference clock buffer; and
an integrity check circuit arrangement in electrical connection with the first flip flop and the second flip flop.

3. The circuit arrangement according to claim 2,
wherein the first flip flop comprises:
a clock input port in electrical connection with an output of the monitoring tunable clock buffer;
a data input port;
an output port in electrical connection with the integrity check circuit arrangement; and
an inverted output port in electrical connection with the data input port.

4. The circuit arrangement according to claim 2,
wherein the second flip flop comprises:
a clock input port in electrical connection with an output of the reference clock buffer;
a data input port;
an output port in electrical connection with the set input port with the integrity check circuit arrangement; and
an inverted output port in electrical connection with the data input port.

5. The circuit arrangement according to claim 2,
wherein the integrity check circuit arrangement comprises:
an exclusive OR gate (XOR gate) having an input in electrical connection with the first flip flop and the second flip flop;
a shift-up register in electrical connection to an output of the exclusive OR gate (XOR gate); and
a shift-down register in electrical connection to the output of the exclusive OR gate (XOR gate).

6. The circuit arrangement according to claim 5,
wherein the exclusive OR gate (XOR gate) is configured to detect the glitch comprised in the monitoring clock signal by comparing a first signal from the first flip flop and a second signal from the second flip flop; and
wherein the exclusive OR gate (XOR gate) is configured to transmit a glitch flag signal to the shift-up register and the shift-down register upon detecting the glitch.

7. The circuit arrangement according to claim 6,
wherein the voltage generation circuit arrangement comprises:
a voltage source;
a voltage divider in electrical connection with the voltage source, the voltage divider configured to generate different voltages based on a fixed voltage of the voltage source;
a first multiplexer in electrical connection with the voltage divider and the shift-up register; and
a second multiplexer in electrical connection with the voltage divider and the shift-down register.

8. The circuit arrangement according to claim 7,
wherein the first multiplexer comprises a first plurality of electrical lines configured to receive the different voltages, each line comprising a switch; and
wherein the second multiplexer comprises a second plurality of electrical lines configured to receive the different voltages, each line comprising a switch.

9. The circuit arrangement according to claim 8,
wherein the shift-up register is configured to transmit the one or more first control signals to the first multiplexer upon receiving the glitch flag signal, thereby adjusting the first adjustable voltage by controlling the first plurality of switches; and
wherein the shift-down register is configured to transmit the one or more second control signals to the second multiplexer upon receiving the glitch flag signal, thereby adjusting the second adjustable voltage by controlling the second plurality of switches.

10. The circuit arrangement according to claim 9,
wherein the voltage generation voltage is configured so that at any one time, only one of the first plurality of switches is activated to select one voltage of the plurality of voltages for generating the first adjustable voltage, and only one of the second plurality of switches is activated to select one voltage of the plurality of voltages for generating the second adjustable voltage.

11. The circuit arrangement according to claim 7,
wherein the voltage divider comprises a plurality of resistors connected in series for generating the different voltages.

12. The circuit arrangement according to claim 1,
wherein the monitoring tunable clock buffer, the reference clock buffer, and the one or more further tunable clock buffers each comprises:
an inverter having an input and an output; and
a tuning circuit arrangement in electrical connection with the input of the inverter.

13. The circuit arrangement according to claim 12,
wherein the tuning circuit arrangement of each of the monitoring tunable clock buffer, the reference clock buffer, and the one or more further tunable clock buffers comprises:
a first n-channel field effect transistor having a control electrode, a first controlled electrode and a second controlled electrode;
a second n-channel field effect transistor having a control electrode, a first controlled electrode and a second controlled electrode;
a first p-channel field effect transistor having a control electrode, a first controlled electrode and a second controlled electrode; and
a second p-channel field effect transistor having a control electrode, a first controlled electrode and a second controlled electrode.

14. The circuit arrangement according to claim 13,
wherein the first controlled electrode of the first p-channel field effect transistor is connected to a supply voltage;
wherein the first controlled electrode of the second p-channel field effect transistor is connected to the second controlled electrode of the first p-channel field effect transistor;
wherein the first controlled electrode of the first n-channel field effect transistor is connected to the second controlled electrode of the second p-channel field effect transistor and to the input of the inverter;
wherein the first controlled electrode of the second n-channel field effect transistor is connected to the second controlled electrode of the first n-channel field effect transistor;
wherein the second controlled electrode of the second n-channel field effect transistor is connected to ground; and
wherein the control electrode of the first p-channel field effect transistor and the control electrode of the second n-channel field effect transistor are in electrical connection with the clock source.

15. The circuit arrangement according to claim 14,
where the control electrode of the second p-channel field effect transistor comprised in each of the monitoring tunable clock buffer and the one or more further tunable clock buffers is in electrical connection with the voltage generation circuit arrangement to receive the first adjustable voltage; and
wherein the control electrode of the first n-channel field effect transistor comprised in each of the monitoring tunable clock buffer and the one or more further tunable clock buffers is in electrical connection with the voltage generation circuit arrangement to receive the second adjustable voltage.

16. The circuit arrangement according to claim 14,
where the control electrode of the second p-channel field effect transistor comprised in the reference clock buffer is in electrical connection with the voltage generation circuit arrangement to receive the first fixed reference voltage; and
wherein the control electrode of the first n-channel field effect transistor comprised in the reference clock buffer is in electrical connection with the voltage generation circuit arrangement to receive the second fixed reference voltage.

17. The circuit arrangement according to claim 1,
wherein each of the first adjustable voltage and the second adjustable voltage is a positive voltage or ground.

18. The circuit arrangement according to claim 1,
wherein the reference clock signal is devoid of the glitch due to the reference delay.

19. The circuit arrangement according to claim 1,
wherein the glitch is generated by exposing the clock source to radiation.

20. A method of forming a clocking circuit arrangement:
providing a clock source configured to generate a clock source signal;
connecting a global monitoring circuit arrangement to the clock source, the global monitoring circuit arrangement comprising:
a monitoring tunable clock buffer in electrical connection with the clock source, the tunable clock buffer configured to generate a monitoring clock signal based on a first adjustable voltage, a second adjustable voltage, and the clock source signal;
a reference clock buffer in electrical connection with the clock source, the reference clock buffer configured to generate a reference clock signal comprising a reference delay based on a first fixed reference voltage, a second fixed reference voltage, and the clock source signal;
a glitch capturing circuit arrangement in electrical connection to the monitoring tunable clock buffer and the reference clock buffer, the glitch capturing circuit arrangement configured to detect a glitch comprised in the monitoring clock signal based on the monitoring clock signal and the reference clock signal; and
a voltage generation circuit arrangement in electrical connection with the glitch capturing circuit arrangement; and
connecting a main circuit arrangement to the clock source, the main circuit arrangement comprising:
one or more further tunable clock buffers in electrical connection with the clock source, each of the one or more further tunable clock buffers configured to generate an output clock signal based on the first adjustable voltage, the second adjustable voltage, and the clock source signal;
wherein the glitch capturing circuit arrangement is configured to transmit one or more first control signals and one or more second control signals to the voltage generation circuit arrangement upon detecting a glitch comprised in the monitoring clock signal;
wherein the voltage generation circuit arrangement is also in electrical connection with the monitoring tunable clock buffer and each of the one or more further tunable clock buffers for transmitting the first adjustable voltage and the second adjustable voltage to the monitoring tunable clock buffer and each of the one or more tunable clock buffers; and
wherein the voltage generation circuit arrangement is configured to adjust the first adjustable voltage and the second adjustable voltage upon receiving the one or more first control signals and the one or more second control signals from the glitch capturing circuit arrangement so that the output clock signal generated by at least one tunable clock buffer of the one or more tunable clock buffers comprises a suitable delay for compensating a corresponding glitch in an input signal provided to the at least one tunable clock buffer.
